(19) United States
(12) Patent Application Publication
(10) Pub. No.: US 2026/0331338 A1
(43) Pub. Date: Oct. 22, 2026

(54) POWER MODULE

(71) Applicants: NEXPERIA TECHNOLOGY (SHANGHAI) LTD., Shanghai (CN); NEXPERIA B.V., Nijmegen (NL)

(72) Inventors: Helen Huang, Suzhou (CN); Tina Hu, Suzhou (CN)

(73) Assignees: NEXPERIA TECHNOLOGY (SHANGHAI) LTD., Shanghai (CN); NEXPERIA B.V., Nijmegen (NL)

(21) Appl. No.: 19/693,690

(22) Filed: Jun. 1, 2026

Related U.S. Application Data
(63) Continuation of application No. PCT/CN2023/135560, filed on Nov. 30, 2023.

(51) Int. Cl. H01C 1/14; H01C 1/012; H01C 17/28; H10D 80/20; H10W 40/20; H10W 40/22; H10W 40/25; H10W 40/60; H10W 70/00; H10W 70/60; H10W 72/00; H10W 74/10; H10W 76/15; H10W 90/00; H10W 90/10

(52) U.S. Cl. CPC H01C 1/1413; H01C 1/012; H01C 17/28; H10D 80/213; H10W 40/255; H10W 70/099; H10W 70/611; H10W 40/226; H10W 40/235; H10W 40/611; H10W 72/884; H10W 74/114; H10W 76/15; H10W 90/10; H10W 90/734; H10W 90/754

(57) ABSTRACT

A power module is provided. The power module includes a substrate that defines a first major surface, a component that defines a first end, a second end, and longitudinal axis. The first end of the component is secured to the substrate so that the longitudinal axis of the component extends substantially perpendicular to the first major surface of the substrate. The power module further includes a pin that defines a longitudinal axis, the pin being secured to the second end of the component so that the longitudinal axis of the pin is substantially parallel to the longitudinal axis of the component.

### CROSS-REFERENCE TO RELATED APPLICATIONS

This application is a continuation of PCT/CN2023/135560 filed on Nov. 30, 2023, the contents of which are incorporated by reference herein in their entirety.

### BACKGROUND

### 1. Field of the Disclosure

The present disclosure relates to a power module, and to a method of manufacturing a power module.

### 2. Description of the Related Art

Power modules are commonly used in inverter systems. Power modules are used to convert the power supply from alternating current (AC) to direct current (DC), and to ensure that the power is supplied to a component, such as an electric motor, at the correct voltage and current.

Power modules include various components which serve to monitor one or more operating parameters or conditions.

The present disclosure seeks to obviate, or at least mitigate, the problems associated with known apparatus, whether identified herein or otherwise.

### SUMMARY

In a first aspect of the present disclosure, there is provided a power module. The power module comprises a substrate that defines a first major surface. The power module further comprises component. The component defines a first end, a second end, and longitudinal axis. The first end of the component is secured to the substrate such that the longitudinal axis of the component extends substantially perpendicular to the first major surface of the substrate. The power module further comprises a pin that defines a longitudinal axis. The pin is secured to the second end of the component such that the longitudinal axis of the pin is substantially parallel to the longitudinal axis of the component.

Here and throughout this document, one part being secured to another does not necessarily mean that the two parts are in direct contact, but a layer of adhesive or solder may be disposed between the parts to secure them together. For example, the component may be secured to the substrate by virtue of a solder layer.

The component can be any shape, preferably an elongate shape. Where the component is an elongate shape, the longitudinal axis of the component may extend in a direction that is generally parallel to a largest dimension of the component. However, the component need not be elongate. Where the component is not elongate, the longitudinal axis of the component extends centrally through the component, and so the longitudinal axis may be referred to as a central axis.

Components are typically mounted to the substrate such that their longitudinal axis extends parallel to a major surface of the substrate. Since the longitudinal axis of the component extends substantially perpendicular to the first major surface of the substrate, the footprint of the component is reduced. Furthermore, pins are often positioned adjacent a component to which it is in electrical communication with. Since the pin is secured to the second end of the component so that its longitudinal axis is substantially parallel to the longitudinal axis of the component, the footprint of the pin on the first major surface of the substrate is removed. This is because the pin is not in direct contact with the first major surface of the substrate. This advantageously allows for a larger die that would otherwise be possible to be secured to the substrate. Use of a larger die improves the functionality of the power module.

Here and throughout this document, the term ‘footprint’, with regards to a component, may be understood to refer to an area of the component when viewed in plan view.

The component can be a resistor, a capacitor or an inductor.

Where the component is a resistor, the resistor can be a negative temperature coefficient (NTC) resistor.

The component can be secured to the substrate using a first solder layer. The pin can be secured at the second end of the component using a second solder layer.

A melting temperature of the second solder layer can be less than a melting temperature of the first solder layer.

Advantageously this better secures the component to the substrate. This is because the likelihood of the first solder layer melting during reflow of the second solder layer, which occurs during manufacture of the power module, is reduced.

The longitudinal axis of the pin can extend from the longitudinal axis of the component.

A plurality of components can be secured to the first major surface of the substrate. Each component of the plurality of components can define a respective first end, second end, and longitudinal axis. Each component of the plurality of components can be secured to the first major surface of the substrate such that their respective longitudinal axes extend substantially perpendicular to the first major surface of the substrate.

The power module can further comprise a plurality of pins that each define a longitudinal axis. Each pin of the plurality of pins can be secured to a second end of a respective component of the plurality of components such that the longitudinal axis of each pin is substantially parallel to the longitudinal axis of the respective component.

The plurality of components can include one or more resistors, capacitors, and/or inductors.

In a second aspect of the disclosure, there is provided a method of manufacturing a power module. The method comprises: providing a substrate, the substrate defining a first major surface; providing a component, the component defining a first end, a second end, and a longitudinal axis; securing the first end of the component to the first major surface of the substrate so that the longitudinal axis of the component extends substantially perpendicular to the first major surface; providing a pin that defines a longitudinal axis; and securing the pin to the second end of the component such that the longitudinal axis of the pin is generally parallel to the longitudinal axis of the component.

It will be appreciated that the advantages discussed above in relation to the first aspect of the disclosure apply mutatis mutandis to this aspect of the invention.

### BRIEF DESCRIPTION OF THE DRAWINGS

Embodiments of the present disclosure will now be described with reference to the accompanying drawings, in which:

FIG. 1 shows a perspective view of a power module according to an embodiment of the present disclosure.

FIG. 2 shows a cross-sectional view the power module of FIG. 1.

FIG. 3 shows a resistor of the power module of FIG. 1.

FIG. 4 show a pin of the power module of FIG. 1.

FIGS. 5, 6, 7, 8, 9, 10, 11 and 12 show a method of manufacture of the power module of FIG. 1.

### DETAILED DESCRIPTION

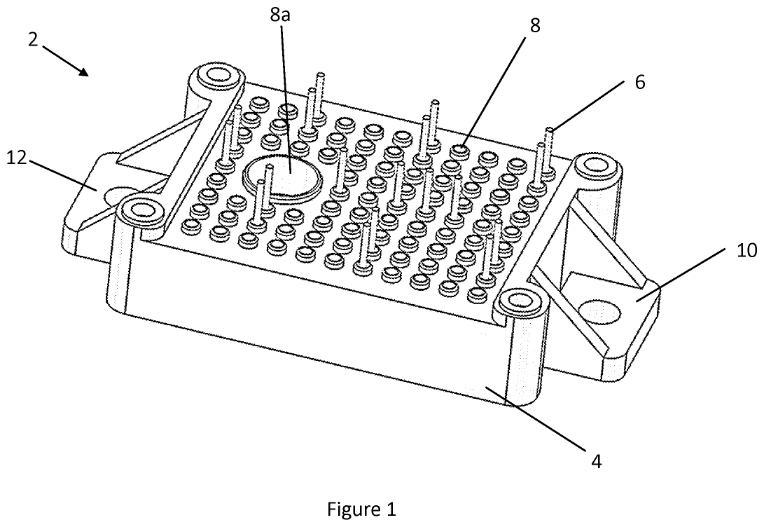

FIG. 1 shows a power module 2 according to an embodiment of the present disclosure. The power module 2 comprises a casing 4. The casing 4 surrounds or at least partially surrounds the remaining components of the power module 2. A plurality of pins 6 each extend through a respective aperture of a plurality of apertures 8 that are defined in the casing 4. One of the apertures 8a of the plurality of apertures 8 is larger (i.e., has a greater cross-sectional area) than the others. In the embodiment shown in FIG. 1, there are fewer pins 6 than there are apertures 8, as is typical for power modules. However, this need not be the case. It will be appreciated that the quantity and locations of the pins is not limited to the quantity and locations depicted in FIG. 1. The plurality of pins 6 are connectable to an external device (not shown) to allow communication between the power module 2 and the external device. The casing 4 comprises a first mounting portion 10 and a second mounting portion 12. In the depicted embodiment, the first mounting portion 10 and the second mounting portion 12 are integrally formed with the casing 4. However, in some embodiments, the first and second mounting portions 10, 12 maybe separately formed from the casing 4 and attached by any suitable means, such as using an adhesive.

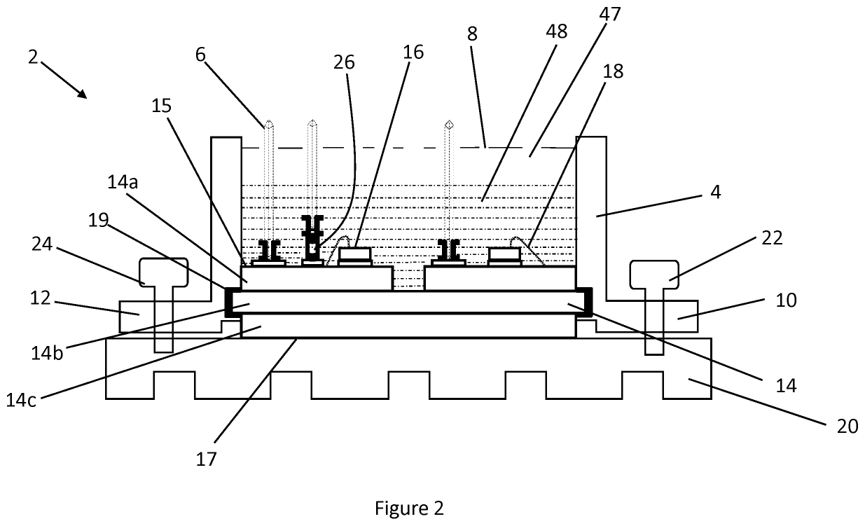

FIG. 2 shows a cross sectional view of the power module 2. The power module 2 further comprises a substrate 14. The substrate 14 is secured to the casing 4 via an adhesive layer 19. The substrate 14 is formed of a laminated structure. The substrate 14 comprises a first copper layer 14a, a ceramic layer 14b, and a second copper layer 14c. The first copper layer 14a and the second copper layer 14c are directly bonded onto opposed sides of the ceramic layer 14b. The substrate 14 may be referred to as a direct bonded copper substrate. In other embodiments the substrate may take any other suitable form. For example, the substrate 14 can comprise a different number of layers, and/or may be formed from different materials. The substrate 14 defines a first major surface 15. The first major surface 15 is a major surface of the first copper layer 14a. The substrate 14 defines a second major surface 17. The second major surface 17 is a major surface of the second copper layer 14c. The second major surface 17 is generally opposed to the first major surface 15. A plurality of dies 16 (only one of which is labelled in FIG. 2) are secured to the first copper layer 14a, as will be discussed in more detail below. In particular, the plurality of dies 16 are secured to the first major surface 15. A plurality of wires 18 (only one of which is labelled in FIG. 2) are provided. The plurality of wires 18 each extend from the substrate 14, in particular the first major surface 15 of the substrate 14, to a respective die of the plurality of dies 16.

The power module 2 further comprises a heat sink 20. The purpose of the heat sink 20 is to increase the amount of heat that dissipates from the power module 2 in use. This reduces the likelihood that the power module 2 overheats in use. A first fastener 22 and a second fastener 24 are provided, which secure the casing 4 to the heat sink 20 via the first mounting portion 10 and the second mounting portion 12 respectively.

A component 26 is secured to the first major surface 15 of the substrate 14. The component 26 can be a resistor, preferably a negative temperature co-efficient (NTC) resistor, a capacitor, or an inductor. The component can be a humidity sensitive resistor, for measuring humidity within the power module 2 may be provided. Alternatively the component can be a fusing resistor, for measuring the current passing through the power module 2 may be provided. In some embodiments, a plurality of components 26 are provided. Where a plurality of components 26 are provided, any combination of the above components 26 may be provided.

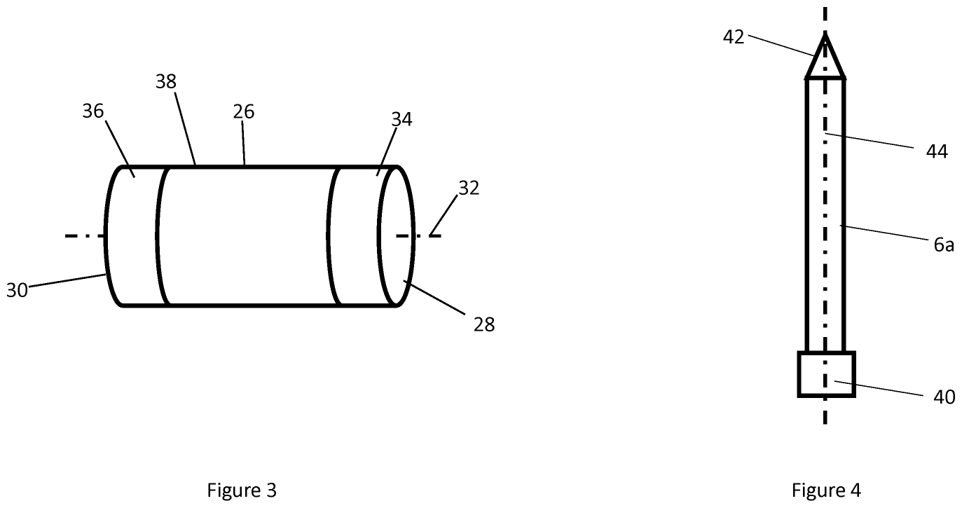

FIG. 3 shows the component 26. As can be seen, the component 26 is generally cylindrical, but can take any other suitable shape. The component 26 comprises a first end 28 and a second end 30. The second end 30 is generally opposed to the first end 28. The component 26 further comprises a longitudinal axis 32. The component 26 comprises a first conductive portion 34, which is provided in the region of the first end 28 of the component. The component 26 comprises a second conductive portion 36, which is provided in the region of the second end 30. An insulating portion 38 is disposed between the first conductive portion 34 and the second conductive portion 36. Although the component 26 is shown as cylindrical, the component 26 can take any other suitable form. The component 26 may be any other shape, preferably an elongate shape. The component 26 being elongate may be understood to mean that one dimension of the component is greater than the other two dimensions of the component. However, the component 26 need not be elongate but may be, for example, cuboidal.

Referring back to FIG. 2, the component 26 is secured to the first major surface 15 of the substrate 14 such that the longitudinal axis 32 extends substantially perpendicular to a plane that is defined by the first major surface 15 of the substrate 14. It is the first end 28 of the component 26 that is secured to the first major surface of the substrate 14. This advantageously reduces the footprint of the component 26 as compared to if the component 26 were to be mounted such that its longitudinal axis were parallel to the first major surface 15. This is desirable because reducing the footprint of the component 26 increases the space of the first major surface 15 that is available for die attachment, which increases the functionality of the power module 2.

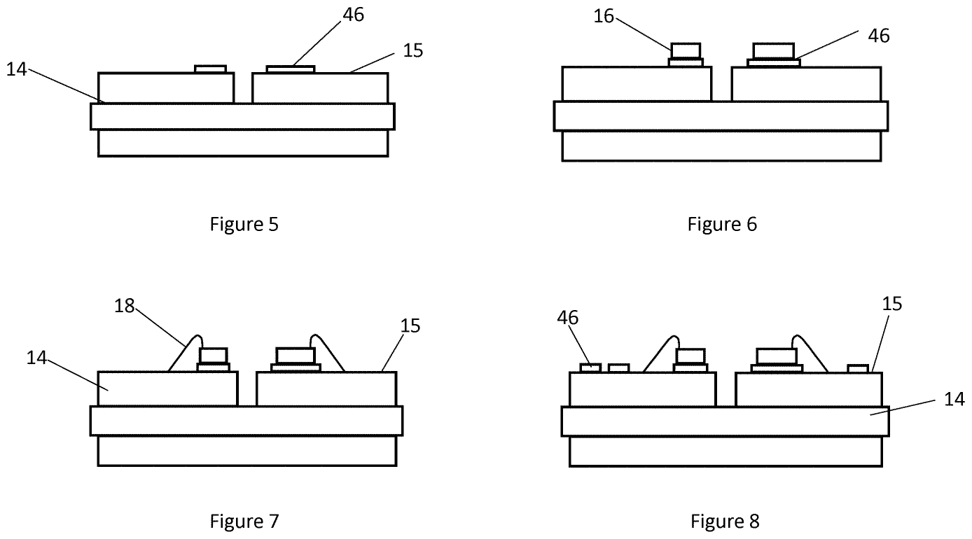

A pin 6a of the plurality of pins 6 is secured to the second end 30 of the component 26. FIG. 4 shows the pin 6a. The pin 6a comprises a first end 40 and a second end 42. The first end 40 defines an attachment portion. The pin 6a defines a longitudinal axis 44. The second end 42 of the pin 6a is connectable to an external device. Although this description has been in relation to the pin 6a, the above may apply to all of the pins of the plurality of pins 6.

Referring back to FIG. 2, the first end 40 of the pin 6a is secured to the second end 30 of the component 26. The pin 6a allows a signal from the component 26 to be communicated to the external device. For example, where the component 26 is an NTC, the signal from the component 26 allows the temperature of the substrate 14 to be determined. The pin 6a is secured to the component 26 such that its longitudinal axis (not shown in FIG. 2 for clarity) is parallel to the longitudinal axis (not shown in FIG. 2 for clarity) of the component 26. The longitudinal axis of the pin 6a may be said to be coincident with the longitudinal axis of the component 26. The longitudinal axis of the pin 6a being parallel to the longitudinal axis of the component 26 advantageously further reduces the space that is occupied on the first major surface 15 of the substrate 14. This is as compared, for example, if the pin 6a were disposed adjacent the component 26.

A cavity 47 is defined by the casing 4. An insulator 48 is received in the cavity 47. The insulator 48 can be made of silicone, such as a silicone gel. The insulator 48 protects the components of the power module 2 that are received in the casing 4 (i.e., the first copper layer 14a, the plurality of dies 16, the plurality of wires 18, and the component 26) from, for example, moisture and dust.

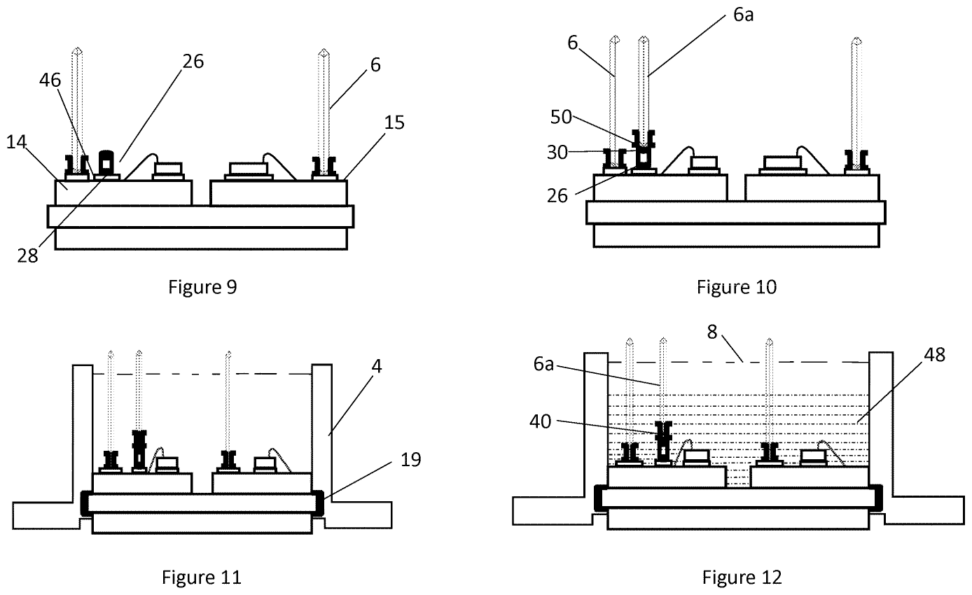

The process by which the power module 2 is manufactured will now be discussed with references to FIGS. 5-11. In a first step the substrate 14 is provided. A first solder layer 46 is applied to the first major surface 15 of the substrate. As can be seen, the first solder layer 46 comprises multiple, separate portions. In some embodiments, the first solder layer 46 comprises only a single portion. The number of portions that the first solder layer 46 comprises may correspond to the number of dies of the plurality of dies (not shown in FIG. 5).

Next, as shown in FIG. 6, the plurality of dies 16 are secured to the first solder layer 46. The plurality of dies 16 are first positioned on the first solder layer 46. As can be seen, each die of the plurality of dies 16 are secured to a respective portion of the first solder layer 46. Once positioned, the assembly (i.e., the substrate 14, the plurality of dies 16, and the first solder layer 46) undergoes reflow. During reflow, the assembly is heated. This makes the bond between the plurality of dies 16 and the substrate 14, in particular to the first major surface 15 of the substrate 14, permanent.

Next, as shown in FIG. 7, the plurality of wires 18 (only one of which is labelled in FIG. 7) are provided. Each wire of the plurality of wires 18 is secured to the first major surface 15 of the substrate 14. Each wire of the plurality of wires 18 may be secured to the first major surface 15 of the substrate 14 via any suitable means, such as by ultrasonic welding. The wires of the plurality of wires 18 are also secured to a respective die of the plurality of dies 16.

Next, as shown in FIG. 8, a second solder layer 48 is applied to the first major surface 15 of the substrate 14. As with the first solder layer 46, the second solder layer 48 is also formed of multiple, separate portions. However, in some, non-depicted embodiments, the second solder layer 48 may be comprised of a single portion. The number of portion of the second solder layer 48 corresponds to the number of pins of the plurality of pins (not shown in FIG. 8).

Next, as shown in FIG. 9, the component 26 is provided. In some embodiments, a plurality of components 26 can be provided. The plurality of pins 6, excluding the pin 6a, are also provided. The component 26 is secured to the first major surface 15 of the substrate 14. In particular, the first end 28 of the component 26 is secured to the first major surface 15 of the substrate 14. As can be seen, the longitudinal axis (not shown) of the component extends generally perpendicular to the first major surface 15 of the substrate 14. The plurality of pins 6 are secured to the first major surface 15 of the substrate 14. This is done by securing the plurality of pins 6 and the NCT 26 to a respective portion of the second solder layer 48. A third solder layer (not shown in FIG. 9) is then applied to the second end 30 of the component 26. Where a plurality of components are provided, each component of the plurality of components may be secured to the first major surface 15 of the substrate 14 in the same manner as the component 26.

Next, as shown in FIG. 10, the pin 6a of the plurality of pins 6 is provided. The pin 6a of the plurality of pins 6 is secured to the component 26, in particular to the second end 30 of the component 26. The pin 6a of the plurality of pins 6 is secured to the component 26 by virtue of the third solder layer 50. The pin 6a is secured to the component 26 such that the longitudinal axis (not shown in FIG. 10 for clarity) of the component 26 is parallel to the longitudinal axis (not shown in FIG. 10 for clarity) of the pin 6a. Preferably, the longitudinal axis of the pin 6a is coincident with the longitudinal axis of the component 26. Where the longitudinal axes 32, 44 are coincident, it is considered that the longitudinal axes 32, 44 extends beyond the component 26 and beyond the pin 6a respectively. Alternatively, it may be considered that the longitudinal axis 42 of the pin 6a extends from, and is parallel with, the longitudinal axis 32 of the component 26. Where a plurality of components 26 are provided, a pin of the plurality of pins 6 can be secured to a respective component of the plurality of components in the same manner than the pin 6a is secured to the component 26.

As is shown in FIG. 11, the casing 4 is then provided. The casing 4 is provided with the adhesive layer 19 pre-applied. The casing 4 is provided so that each pin of the plurality of pins 6 extends through a respective aperture of the plurality of apertures 8.

Next, as shown in FIG. 12, the insulator 48 is provided. The insulator 48 is provided via an apertures, in particular the larger aperture (not visible in FIG. 12), of the plurality of apertures 8. The insulator 48 is preferably provided in liquid form. The insulator 48 is provided so that it covers the first end 40 of the pin 6a. The insulator 48 is then allowed to solidify.

Finally, as shown in FIG. 2, the casing 4 is secured to the heat sink 20. As discussed above, the casing 4 is secured to the heat sink 20 by virtue of the first fastener 22 and the second fastener 24. The first fastener 22 and the second fastener 24 each extend through the first mounting portion 10 and the second mounting portion 12 of the casing 4 respectively. The first fastener 22 and the second fastener 24 are secured to respective fastening portions (not shown in FIG. 2 for clarity) of the heat sink 20.

While specific embodiments of the present disclosure have been described above, it will be appreciated that the disclosure can be practiced otherwise than as described. The descriptions above are intended to be illustrative, not limiting. Thus, it will be apparent to one skilled in the art that modifications can be made to the disclosure as described without departing from the scope of the claims set out below.

1. A power module comprising:
a substrate that defines a first major surface;
a component that defines a first end, a second end, and a longitudinal axis, wherein the first end of the component is secured to the substrate so that the longitudinal axis of the component extends substantially perpendicular to the first major surface of the substrate; and
a pin that defines a longitudinal axis, the pin being secured to the second end of the component so that the longitudinal axis of the pin is substantially parallel to the longitudinal axis of the component.

2. The power module of claim 1, wherein the component is selected from the group consisting of: a resistor, a capacitor, and an inductor.

3. The power module of claim 2, wherein the component is a resistor, and wherein the resistor is a negative temperature coefficient (NTC) resistor.

4. The power module of claim 1, wherein the component is secured to the substrate using a first solder layer, and wherein the pin is secured at the second end of the component using a second solder layer.

5. The power module of claim 4, wherein the second solder layer has a melting temperature that is less than a melting temperature of the first solder layer.

6. The power module of claim 1, wherein the longitudinal axis of the pin extends from the longitudinal axis of the component.

7. The power module of claim 1, further comprising a plurality of components that are secured to the first major surface of the substrate, each component of the plurality of components defining a respective first end, second end, and longitudinal axis, and wherein each component of the plurality of components is secured to the first major surface of the substrate so that their respective longitudinal axes extend substantially perpendicular to the first major surface of the substrate.

8. The power module of claim 7, further comprising a plurality of pins that each define a longitudinal axis, each pin of the plurality of pins being secured to a second end of a respective component of the plurality of components so that the longitudinal axis of each pin is substantially parallel to the longitudinal axis of the respective component.

9. The power module of claim 7, wherein the plurality of components include one or more components selected from the group consisting of: resistors, capacitors, and inductors.

10. The power module of claim 8, wherein the plurality of components include one or more components selected from the group consisting of: resistors, capacitors, and inductors.

11. The power module of claim 2, wherein the component is secured to the substrate using a first solder layer, and wherein the pin is secured at the second end of the component using a second solder layer.

12. The power module of claim 2, wherein the longitudinal axis of the pin extends from the longitudinal axis of the component.

13. The power module of claim 2, further comprising a plurality of components that are secured to the first major surface of the substrate, each component of the plurality of components defining a respective first end, second end, and longitudinal axis, and wherein each component of the plurality of components is secured to the first major surface of the substrate so that their respective longitudinal axes extend substantially perpendicular to the first major surface of the substrate.

14. The power module of claim 3, wherein the component is secured to the substrate using a first solder layer, and wherein the pin is secured at the second end of the component using a second solder layer.

15. The power module of claim 3, wherein the longitudinal axis of the pin extends from the longitudinal axis of the component.

16. The power module of claim 3, further comprising a plurality of components that are secured to the first major surface of the substrate, each component of the plurality of components defining a respective first end, second end, and longitudinal axis, and wherein each component of the plurality of components is secured to the first major surface of the substrate so that their respective longitudinal axes extend substantially perpendicular to the first major surface of the substrate.

17. The power module of claim 4, wherein the longitudinal axis of the pin extends from the longitudinal axis of the component.

18. The power module of claim 4, further comprising a plurality of components that are secured to the first major surface of the substrate, each component of the plurality of components defining a respective first end, second end, and longitudinal axis, and wherein each component of the plurality of components is secured to the first major surface of the substrate so that their respective longitudinal axes extend substantially perpendicular to the first major surface of the substrate.

19. A method of manufacturing a power module, the method comprising the steps of:
providing a substrate, the substrate defining a first major surface;
providing a component, the component defining a first end, a second end, and a longitudinal axis;
securing the first end of the component to the first major surface of the substrate so that the longitudinal axis of the component extends substantially perpendicular to the first major surface;
providing a pin that defines a longitudinal axis; and
securing the pin to the second end of the component so that the longitudinal axis of the pin is generally parallel to the longitudinal axis of the component.
